(19) United States
(12) Patent Application Publication
(10) Pub. No.: US 2019/0157609 A1
(43) Pub. Date: May 23, 2019

(54) DISPLAY DEVICE

(71) Applicant: Japan Display Inc., Minato-ku (JP)

(72) Inventor: Takayasu SUZUKI, Minato-ku (JP)

(73) Assignee: Japan Display Inc., Minato-ku (JP)

(21) Appl. No.: 16/189,058

(22) Filed: Nov. 13, 2018

(30) Foreign Application Priority Data
Nov. 20, 2017 (JP) 2017-222725

(51) Int. Cl. H01L 51/52; H05K 5/00

(52) U.S. Cl. CPC H01L 51/5246; H01L 27/3276; H01L 2251/5338; H05K 5/0017

(57) ABSTRACT

A display device may have a flexible display having a display area and a support member having a first surface and a second surface opposite to each other. The first surface is adhered to the flexible display. The support member has a first part including a plurality of tapered portions arranged along the first surface and tapered in a direction toward the second surface. The support member has a second part made from a softer material than the plurality of tapered portions. The second part connects an adjacent pair of the plurality of tapered portions. The display device has a neutral plane, which is free from expansion and contraction when the display device is bent. The neutral plane is closer to the first surface than the second surface.

### CROSS-REFERENCE TO RELATED APPLICATION

The present application claims priority from Japanese application JP2017-222725 filed on Nov. 20, 2017, the content of which is hereby incorporated by reference into this application.

### BACKGROUND

### 1. Field

This relates to display devices.

### 2. Description of the Related Art

Flexible displays have been developed for display devices. A known display device may have a flexible resin substrate on which a circuit layer and organic light emitting diodes (OLEDs) are formed (JP 2011-227369A).

The flexible displays tend to have a support member adhered thereon to withstand repeated bending and stretching. The support member and the flexible display are preferably difficult to detach. The support member requires no stress concentration.

### SUMMARY

This is to aim at compatible flexibility and durability.

A display device may have a flexible display having a display area and a support member having a first surface and a second surface opposite to the first surface. The first surface is adhered to the flexible display. The support member has a first part including a plurality of tapered portions arranged along the first surface and tapered in a direction toward the second surface. The support member has a second part made from a softer material than the plurality of tapered portions. The second part connects an adjacent pair of the plurality of tapered portions. The display device has a neutral plane, which is free from expansion and contraction when the display device is bent. The neutral plane is closer to the first surface than the second surface.

The second part made from a soft material is between adjacent tapered portions, dispersing stress, making flexibility and durability compatible.

### BRIEF DESCRIPTION OF THE DRAWINGS

FIG. 1 is a perspective view of a display device in an embodiment.

FIG. 2 is a II-II line cross-sectional view of the display device in FIG. 1.

FIG. 3 is an enlarged view of a portion III in FIG. 2.

FIG. 4 is a rear view of a part of a first layer.

FIG. 5 is a perspective view of usage of the display device in FIG. 1.

FIG. 6 is a cross-sectional view of a support member in use in FIG. 5.

FIG. 7 is a cross-sectional view of variation 1 of the embodiment.

FIG. 8 is a cross-sectional view of variation 2 of the embodiment.

FIG. 9 is a rear view of variation 3 of the embodiment.

FIG. 10 is a rear view of variation 4 of the embodiment.

FIG. 11 is a rear view of variation 5 of the embodiment.

FIG. 12 is a perspective view of variation 6 of the embodiment.

FIG. 13 is a perspective view of variation 7 of the embodiment.

### DETAILED DESCRIPTION

Hereinafter, some embodiments will be described with reference to the drawings. Here, the invention can be embodied according to various aspects within the scope of the invention without departing from the gist of the invention and is not construed as being limited to the content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

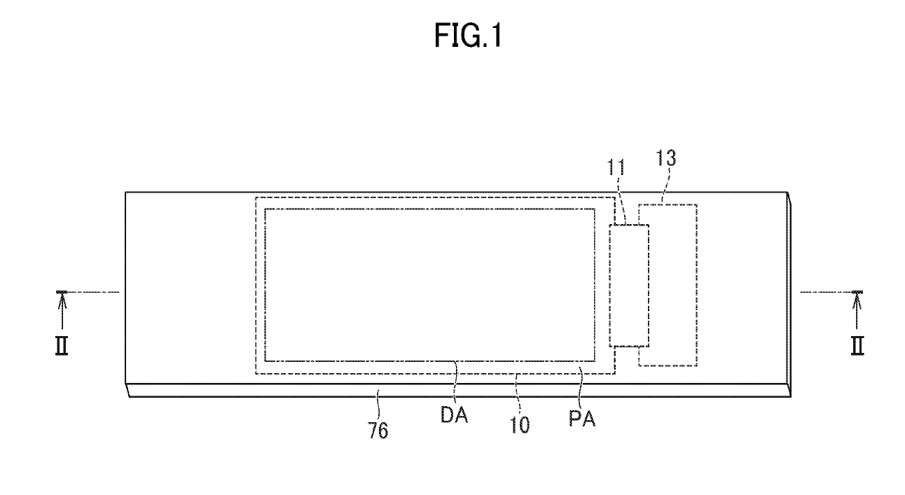

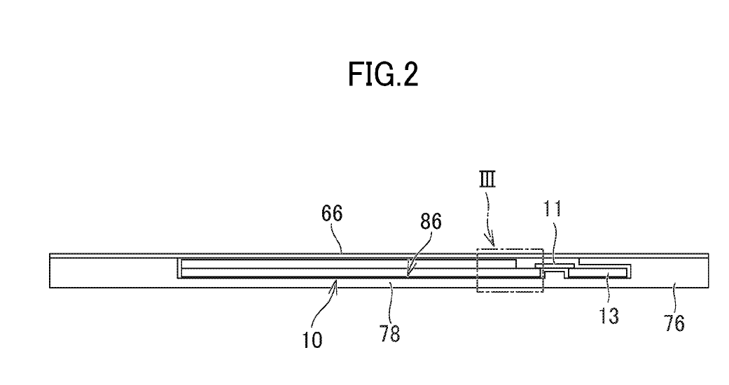

FIG. 1 is a perspective view of a display device in an embodiment. FIG. 2 is a II-II line cross-sectional view of the display device in FIG. 1.

The display device is an organic electroluminescence (EL) display device. The display device has a flexible display 10. The flexible display 10 is configured to display a full-color image by forming full-color pixels, each of which consists of unit pixels (sub-pixels) in some colors such as red, green, and blue. The flexible display 10 includes a display area DA and a peripheral area PA around the display area DA. The peripheral area PA is outside the display area DA.

A flexible printed circuit board 11 is connected to the peripheral area PA. The flexible printed circuit board 11 has an integrated circuit (not shown) mounted thereon for controlling an element to display the image. A printed circuit board 13 is connected to the flexible printed circuit board 11. The printed circuit board 13 has some sort of electronic component (not shown) mounted thereon.

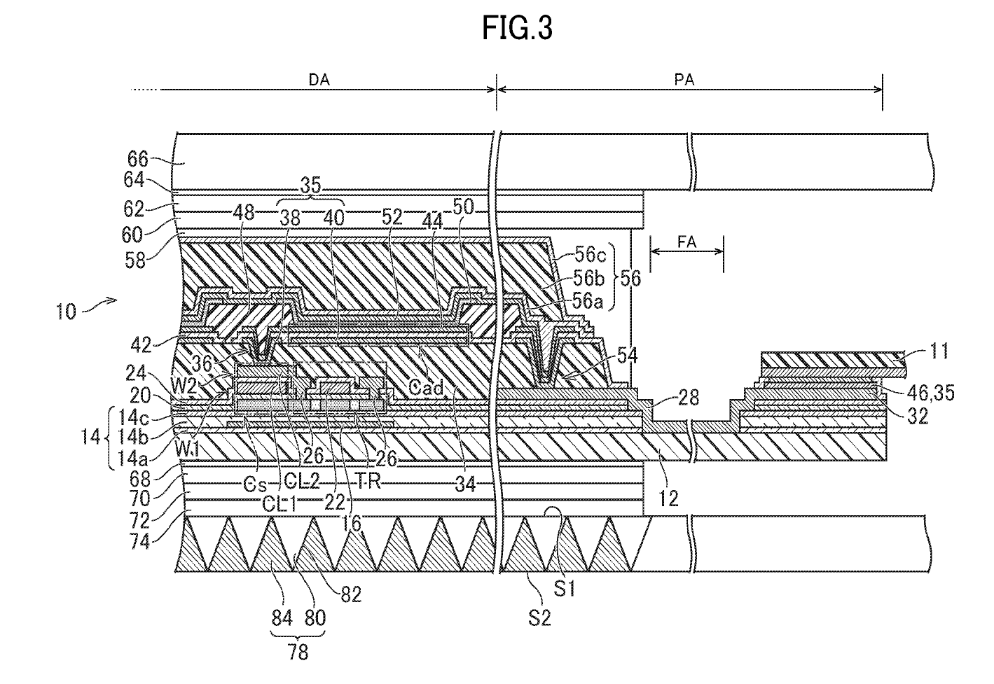

FIG. 3 is an enlarged view of a portion III in FIG. 2. The flexible display 10 has a substrate 12 (array substrate). The substrate 12 is made from polyimide. Or, other resin materials can be used as long as the materials have enough flexibility. A three-layer laminate structure consisting of a silicon oxide film 14a, a silicon nitride film 14b, and a silicon oxide film 14c, is on the substrate 12 for an undercoat layer 14. The silicon oxide film 14a in the lowest layer is for improving a close-fitting property with the substrate 12; the silicon nitride film 14b in the middle layer is for a blocking film from external moisture and impurities; the silicon oxide film 14c in the uppermost layer is for another blocking film to prevent hydrogen atoms in the silicon nitride film 14b from diffusing on a side of a semiconductor layer 18 of a thin film transistor TR. Such a structure, however, is not essential. Another layer may be laminated, and a single-layer or a two-layer laminate is applicable thereto.

An additional film 16 maybe formed under the undercoat layer 14 to correspond to an area where the thin film transistor TR is formed. The additional film 16 may curb a characteristic change of the thin film transistor TR due to light intrusion from its channel back or may provide the thin film transistor TR with a backgating effect by being formed from a conductive material to apply a certain potential. In this embodiment, after the silicon oxide film 14a is formed, the additional film 16 is formed in an island shape corresponding to an area where the thin film transistor TR is formed, and then the silicon nitride film 14b and the silicon oxide film 14c are laminated, whereby the additional film 16 is sealed in the undercoat layer 14. Alternatively, the undercoat layer 14 may be made after the additional film 16 is formed on the substrate 12.

The thin film transistor TR is on the undercoat layer 14. A polysilicon thin film transistor is illustrated and only an N-ch transistor is herein shown but a P-ch transistor may be simultaneously formed. The semiconductor layer 18 in the thin film transistor TR has a structure where a low-concentration impurity area is provided between a channel area and a source/drain area. A silicon oxide film is herein used for a gate insulation film 20. A gate electrode 22 is a part of a first trace layer W1 made from MoW. The first trace layer W1 includes a first storage capacitor line CL1 in addition to a gate electrode 22. A part of a storage capacitor Cs is formed between the first storage capacitor line CL1 and the semiconductor layer 18 (source/drain area) with the gate insulation film 20 interposed therebetween.

An interlayer dielectric 24 (silicon oxide film and silicon nitride film) is on the gate electrode 22. At least a part of the interlayer dielectric 24 is removed to make the substrate 12 more flexible and foldable at a folding area FA. Removing the part of the interlayer dielectric 24 exposes the undercoat layer 14, at least a part of which is also removed by patterning. After removing the part of the undercoat layer 14, polyimide constituting the substrate 12 is exposed. The etching of the undercoat layer 14 may partially etch its polyimide surface and reduce its thickness.

A second trace layer W2, which includes portions for the source/drain electrode 26 and a leading line 28, is on the interlayer dielectric 24. A three-layer laminate structure made of Ti, Al, and Ti is herein employed. The first storage capacitor line CL1 (part of the first trace layer W1) and a second storage capacitor line CL2 (part of the second trace layer W2) constitute another portion of the storage capacitor Cs, with the interlayer dielectric 24 interposed therebetween. The leading line 28 extends to an edge of the substrate 12 and has a terminal 32 for being connected to the flexible printed circuit board 11.

A planarization layer 34 covers the source/drain electrode 26 and the leading line 28 (except for some of their portions). Organic materials such as photosensitive acrylic are often used for the planarization layer 34 because of superior surface flatness, compared with inorganic insulation materials formed by chemical vapor deposition (CVD).

The planarization layer 34 is removed at a pixel contact portion 36 and in the peripheral area PA and has an indium tin oxide (ITO) film 35 formed thereon. The indium tin oxide film 35 includes a first transparent conductive film 38 and a second transparent conductive film 40 separated from each other.

The second trace layer W2, which has its surface exposed by removing the planarization layer 34, is covered with the first transparent conductive film 38. A silicon nitride film 42 is on the planarization layer 34, covering the first transparent conductive film 38. The silicon nitride film 42 has an opening at the pixel contact portion 36. A pixel electrode 44 is laminated on and connected to the source/drain electrode 26 through the opening. The pixel electrode 44 is a reflective electrode, with a three-layer laminate structure consisting of an indium zinc oxide (IZO) film, a silver (Ag) film, and an indium zinc oxide film. Instead of the indium zinc oxide film, an indium tin oxide film may be used. The pixel electrode 44 extends laterally from the pixel contact portion 36 to above the thin film transistor TR.

The second transparent conductive film 40 is adjacent to the pixel contact portion 36 and under the pixel electrode 44 (further under the silicon nitride film 42). The second transparent conductive film 40, the silicon nitride film 42, and the pixel electrode 44 overlap with one another, whereby an additional capacitance Cad is formed.

A third transparent conductive film 46, which is another part of the indium tin oxide film 35, is on a surface of the terminal 32. The third transparent conductive film 46 is formed at the same time as the first transparent conductive film 38 and the second transparent conductive film 40 are formed. The third transparent conductive film 46 on the terminal 32 may serve as a barrier film to prevent an exposed portion of the terminal 32 from being damaged in subsequent processes. The third transparent conductive film 46 is subject to etching environment during patterning of the pixel electrode 44. However, while the indium tin oxide film 35 is formed and pixel electrode 44 is subsequently formed, the indium tin oxide film 35 is annealed to acquire enough resistance to the etching of the pixel electrode 44.

An insulation layer 48, which is called a bank (rib) for a partition of adjacent pixel areas, is on the planarization layer and above the pixel contact portion 36, for example. Photosensitive acrylic may be used for the insulation layer 48 just like the planarization layer 34. The insulation layer 48 has an opening for exposing a surface of the pixel electrode 44 as a light emitting region. The opening preferably has an edge in a gently inclined shape. A steep shape of the opening edge may cause insufficient coverage of an organic electroluminescence (EL) layer 50 formed thereon.

The planarization layer 34 and the insulation layer 48 are in contact with each other through an opening in the silicon nitride film 42 between them. This makes it possible to remove moisture and gas desorbed from the planarization layer 34 through the insulation layer 48 during heat treatment after the insulation layer 48 is formed.

The organic EL layer 50 is made from organic materials and is laminated on the pixel electrode 44. The organic EL layer 50 maybe a single-layer or a structure where a hole transport layer, a light emitting layer, and an electron transport layer are laminated, in an order from the pixel electrode 44. These layers may be formed by vapor deposition, by solvent dispersion and application, by selective formation for the pixel electrode 44 (each sub-pixel), or overall formation over the display area DA. The overall formation may be used for a structure where every sub-pixel emits white light and a desired color wavelength portion thereof passes through a color filter (not shown).

A counter electrode 52 is on the organic EL layer 50. Due to a top emission structure herein employed, the counter electrode 52 is transparent. A Mg layer and an Ag layer may be formed to be a thin film through which outgoing light from the organic EL layer 50 can pass. In comply with the forming order of the organic EL layer 50, the pixel electrode 44 is an anode and the counter electrode 52 is a cathode. The counter electrode 52 is formed over the display area DA, extends to a cathode contact portion 54 next to the display area DA, and is connected to the leading line 28 under the cathode contact portion 54 to be electrically connected to the terminal 32.

A sealing film 56 is on the counter electrode 52. The sealing film 56 may serve to prevent external moisture intrusion into the organic EL layer 50 formed thereunder, necessitating a high gas barrier property. A silicon nitride film 56a, an organic resin layer 56b, and a silicon nitride film 56c are laminated to constitute a laminate structure including a silicon nitride film. A silicon oxide film or an amorphous silicon layer may be formed between the silicon nitride film 56a or 56c and the organic resin layer 56b for improving a close-fitting property, for example.

A touch panel substrate 60 is laminated on the sealing film 56 with an adhesive layer 58 interposed therebetween. At least a part of an unillustrated touch sensing electrode is formed on the touch panel substrate 60. The counter electrode 52 may serve as a part of the touch sensing electrode. A circularly polarizing plate 62 is adhered to the touch panel substrate 60. A cover glass 66 is laminated on the circularly polarizing plate 62 with an adhesive layer 64 interposed therebetween. A back film 70 is laminated on the substrate 12 with an adhesive layer 68 interposed therebetween. A heat spread sheet 72 made from graphite and a cushion sheet 74 may be laminated on the back film 70.

The flexible display 10 is placed in the housing 76 (FIG. 2). A part of the housing 76 is a support member 78 adhered to the flexible display 10. The support member 78 has a first surface S1 and a second surface S2 opposite to each other. The first surface S1 is adhered to the flexible display 10. The support member 78 has a first layer 80.

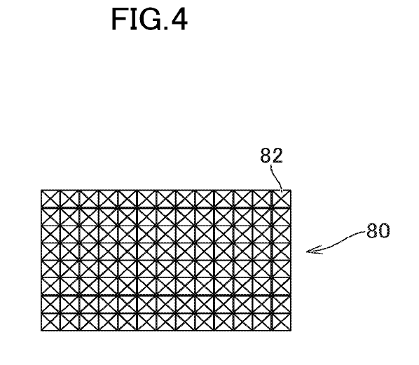

FIG. 4 is a rear view of a part of a first layer 80. The first layer 80 has a plurality of tapered portions 82. Each tapered portion 82 has a shape of a conic solid. The tapered portions 82 are arranged along the first surface S1 in FIG. 3. The tapered portions 82 are integrated with one another at the first surface S1. Each tapered portion 82 is tapered in a direction toward the second surface S2.

As shown in FIG. 3, the support member 78 has a second layer 84. The second layer 84 connects adjacent tapered portions 82. The second layer 84 is made from a material softer than the tapered portions 82. The material constituting the second layer 84 is an elastic material, for example. The second layer 84 is not taller toward the second surface S2 than the tapered portions 82. As shown in FIG. 2, the housing 76 has a recess 86 to contain the flexible display 10 and the printed circuit board 13. The second layer 84 constitutes a bottom surface of the recess 86, which maybe formed by injecting a heated soft resin into a mold.

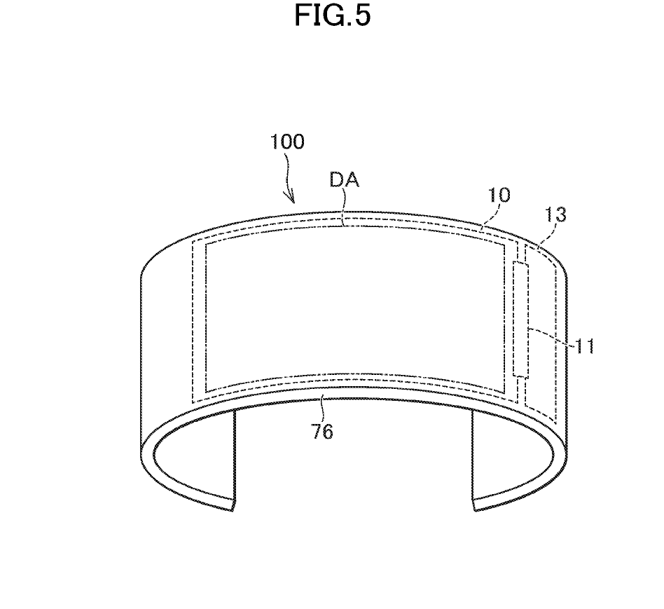

FIG. 5 is a perspective view of usage of the display device in FIG. 1. The display device 100, which includes the flexible display 10 and the support member 78, has at least its part bent for being twisted around a wrist, for example. To prevent its curvature from elastic recovery, an unillustrated holding member may be kept in the housing 76. The flexible display 10 and the flexible printed circuit board 11 in FIG. 1 have flexibility. The printed circuit board 13, which is typically hard to bend, has a shorter length in a direction along an arc described by the bent display device 100. A portion where the printed circuit board 13 is stored may be unbendable.

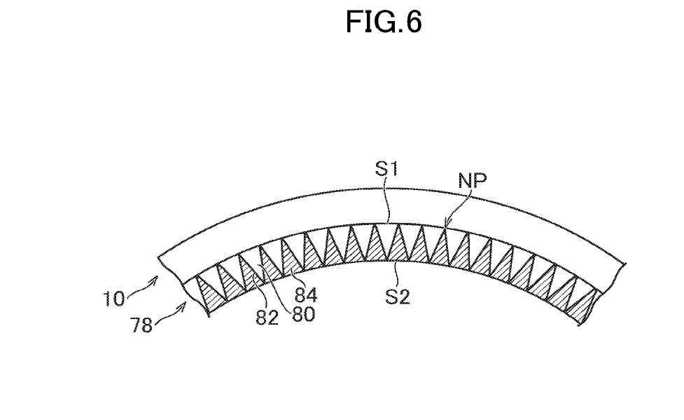

FIG. 6 is a cross-sectional view of a support member 78 in use in FIG. 5. A neutral plane NP, which is free from expansion and contraction when the support member 78 is bent, is closer to the first surface S1 than the second surface S2. The neutral plane NP matches the first surface S1, for example. The embodiment makes it possible to disperse stress because the second layer 84 made from a soft material is between adjacent tapered portions 82, making flexibility and durability compatible.

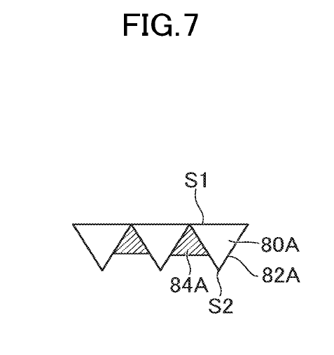

FIG. 7 is a cross-sectional view of variation 1 of the embodiment. FIG. 3 or 6 shows that the second layer 84 is as tall in the direction toward the second surface S2 as the first layer 80 in the direction toward the second surface S2. Contrastingly, FIG. 7 shows that the second layer 84A is shorter in the direction toward the second surface S2 than the first layer 80A in the direction toward the second surface S2. Tips of the tapered portions 82A of the first layer 80A are arranged at the second surface S2.

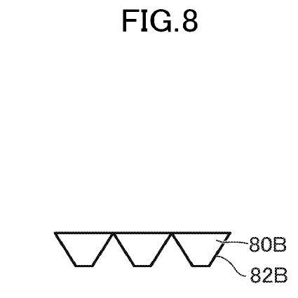

FIG. 8 is a cross-sectional view of variation 2 of the embodiment. In this example, each tapered portion 82B of the first layer 80B has a frustum shape such as a shape of a frustum of a quadrangular pyramid. The tapered portion 82B at its tip has an area. In spite of not being shown in FIG. 8, a second layer is provided between adjacent first layers 80B in such a way as shown in FIG. 3 or 7.

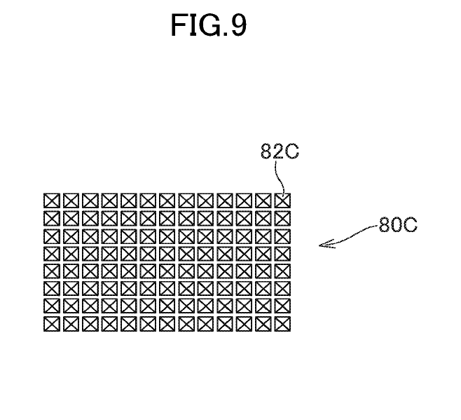

FIG. 9 is a rear view of variation 3 of the embodiment. This example shows that the tapered portions 82C of the first layer 80C are separate from each other.

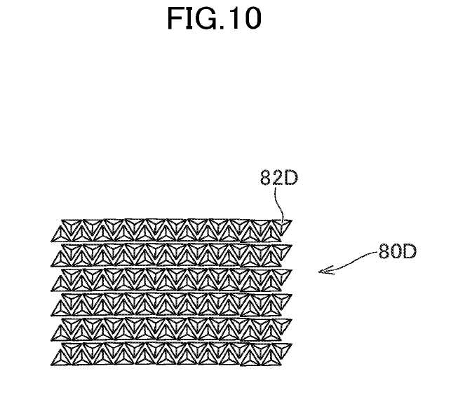

FIG. 10 is a rear view of variation 4 of the embodiment. This example shows that each tapered portion 82D of the first layer 80D has a shape of a frustum of a triangular pyramid.

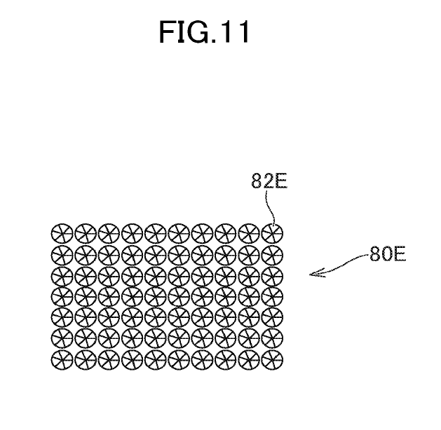

FIG. 11 is a rear view of variation 5 of the embodiment. This example shows that each tapered portion 82E of the first layer 80E has a shape of a circular truncated cone.

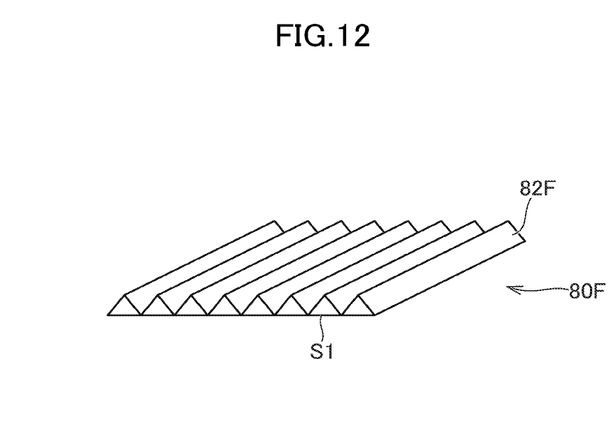

FIG. 12 is a perspective view of variation 6 of the embodiment. This example shows that each tapered portion 82F of the first layer 80F has a shape of a transverse triangular prism. The first surface S1 consists of bottom surfaces (each of which is rectangular) of a plurality of tapered portions 82F. The tapered portion 82F has a tip describing a ridgeline. In spite of not being shown in FIG. 12, a second layer is provided between adjacent first layers 80F in such a way as shown in FIG. 3 or 7.

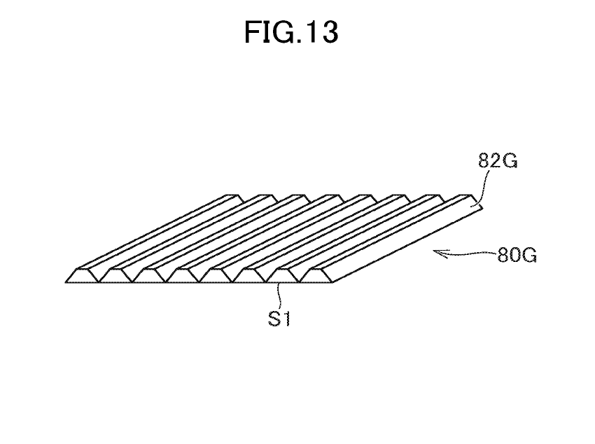

FIG. 13 is a perspective view of variation 7 of the embodiment. This example shows that each tapered portion 82G of the first layer 80G has a shape of an inclined top body, which is a part of a transverse triangular prism left after cutting off its top. The first surface S1 consists of bottom surfaces (each of which is rectangular) of a plurality of tapered portions 82G. The tapered portion 82G at its top has an area. In spite of not being shown in FIG. 13, a second layer is provided between adjacent first layers 80G in such a way as shown in FIG. 3 or 7.

The electronic device is not limited to the organic electroluminescence display device but may be a display device with a light emitting element disposed in each pixel, such as a quantum-dot light emitting diode (QLED), or a liquid crystal display device.

While there have been described what are at present considered to be certain embodiments, it will be understood that various modifications maybe made thereto, and it is intended that the appended claims cover all such modifications as fall within the true spirit and scope of the invention.

What is claimed is:

1. A display device comprising:
a flexible display having a display area; and
a support member having a first surface and a second surface opposite to the first surface, the first surface adhered to the flexible display, wherein
the support member has a first part including a plurality of tapered portions arranged along the first surface and tapered in a direction toward the second surface,
the support member has a second part made from a softer material than the plurality of tapered portions, the second part connecting an adjacent pair of the plurality of tapered portions, and
the display device has a neutral plane, which is free from expansion and contraction when the display device is bent, the neutral plane being closer to the first surface than the second surface.

2. The display device according to claim 1, wherein the material constituting the second part is an elastic material.

3. The display device according to claim 1, wherein the plurality of tapered portions are integrated with one another at the first surface.

4. The display device according to claim 1, wherein the plurality of tapered portions are separate from one another.

5. The display device according to claim 1, wherein the second part is not tall toward the second surface than the plurality of tapered portions.

6. The display device according to claim 1, wherein each of the plurality of tapered portions has a shape of a conic solid or a frustum.

7. The display device according to claim 1, wherein each of the plurality of tapered portions has a shape of an inclined top body or a transverse triangular prism.

8. The display device according to claim 1, wherein each of the flexible display and the support member has curvature in at least a part thereof.

9. The display device according to claim 1, wherein the neutral plane matches the first surface.
